(19) United States
(12) Patent Application Publication
(10) Pub. No.: US 2025/0155285 A1
(43) Pub. Date: May 15, 2025

(54) Photoelectric Conversion Device

(71) Applicant: SHIMADZU CORPORATION, Kyoto-shi (JP)

(72) Inventor: Shunsuke SAKAI, Kyoto-shi (JP)

(21) Appl. No.: 18/943,364

(22) Filed: Nov. 11, 2024

(30) Foreign Application Priority Data
Nov. 13, 2023 (JP) 2023-192695

(51) Int. Cl. G01J 1/44; H03G 3/30

(52) U.S. Cl. CPC G01J 1/44; H03G 3/3084; G01J 2001/4406; G01J 2001/446

(57) ABSTRACT

A photoelectric conversion device includes an amplifier, a photodetector, a first resistor, a second resistor, a first switch, a first terminal, a second terminal, a second switch, a third switch, and a controller. In setting a gain of the amplifier to a second gain, the controller is configured to control the first switch and the third switch to a conducting state and control the second switch to a non-conducting state. In setting the gain of the amplifier to a first gain, the controller is configured to control the first switch and the third switch to the non-conducting state and control the second switch to the conducting state so as to set a potential at one end and a potential at the other end to be equal in the first switch.

### CROSS REFERENCE TO RELATED APPLICATIONS

This nonprovisional application is based on Japanese Patent Application No. 2023-192695 filed with the Japan Patent Office on Nov. 13, 2023, the entire contents of which are hereby incorporated by reference.

### BACKGROUND OF THE INVENTION

### Field of the Invention

The present invention relates to a photoelectric conversion device.

### Description of the Background Art

A photoelectric conversion device converts a current outputted in accordance with light received by a photodetector such as a photodiode into a voltage and outputs the voltage.

Some of such photoelectric conversion devices are provided with a configuration to switch a gain of an amplifier included therein in order to increase a width of levels of light to be detected (Japanese Utility Model Laying-Open No. 1-132113 (full text)). A photoelectric conversion circuit described in Japanese Utility Model Laying-Open No. 1-132113 (full text) is provided with a first resistor for setting of a gain for detection of low-level light and a second resistor for setting of the gain for detection of high-level light, as resistors for setting of the gain of the amplifier.

Japanese Utility Model Laying-Open No. 1-132113 (full text) describes the photoelectric conversion circuit configured as below. A first switch is connected to the first resistor and a second switch is connected to the second resistor. When the first switch is turned on and the second switch is turned off, the gain of the amplifier is set with the first resistor. When the second switch is turned on and the first switch is set to a non-conducting state, the gain of the amplifier is set with the second resistor.

### SUMMARY OF THE INVENTION

When the first switch and the second switch are each implemented by a semiconductor switch in the photoelectric conversion circuit described in Japanese Utility Model Laying-Open No. 1-132113 (full text), however, a problem as below may arise. When the first switch or the second switch is set to the non-conducting state and when potentials at opposing ends of a switch set to the non-conducting state are different from each other, a leakage current may be produced in that switch due to a structure of the semiconductor switch.

When such a leakage current is produced, in the photoelectric conversion circuit, an outputted voltage is set to a level lower than a level of a voltage to originally be outputted, and the photoelectric conversion circuit is unable to output the voltage at a precise level corresponding to received light.

This invention was made to solve such a problem, and an object thereof is to suppress production of a leakage current by a switch that switches a gain of an amplifier in a photoelectric conversion device.

A photoelectric conversion device according to one aspect of this invention includes an amplifier including an inverting input terminal, a non-inverting input terminal, and an output terminal, a photodetector connected between the non-inverting input terminal and the inverting input terminal of the amplifier, a first resistor provided between the inverting input terminal and the output terminal of the amplifier to set a gain of the amplifier to a first gain, a second resistor provided between the inverting input terminal and the output terminal of the amplifier to set the gain of the amplifier to a second gain, a first switch implemented by a semiconductor switch having one end connected to the second resistor and the other end connectable to the output terminal of the amplifier, a first terminal connected to the non-inverting input terminal of the amplifier to receive a reference potential, a second terminal that receives the reference potential, a second switch that allows connection between the other end of the first switch and the second terminal, a third switch that allows connection between the other end of the first switch and the output terminal of the amplifier, and a controller that controls the first switch, the second switch, and the third switch. The controller is configured to control the first switch and the third switch to a conducting state and control the second switch to a non-conducting state in setting the gain of the amplifier to the second gain, and the controller is configured to control the first switch and the third switch to the non-conducting state and control the second switch to the conducting state to set a potential at the one end and a potential at the other end to be equal in the first switch, in setting the gain of the amplifier to the first gain.

The foregoing and other objects, features, aspects and advantages of this invention will become more apparent from the following detailed description of this invention when taken in conjunction with the accompanying drawings.

### BRIEF DESCRIPTION OF THE DRAWINGS

FIG. 1 is a circuit diagram showing a configuration of a photoelectric conversion device 100 in a first embodiment.

FIG. 2 is a circuit diagram showing an exemplary semiconductor switch to be employed as a first switch 1.

FIG. 3 is a flowchart showing exemplary control of first switch 1, a second switch 2, and a third switch 3 in photoelectric conversion device 100.

### DESCRIPTION OF THE PREFERRED EMBODIMENTS

An embodiment of the present invention will be described in detail below with reference to the drawings. The same or corresponding elements in the drawings have the same reference characters allotted below and description thereof will not be repeated in principle. Though a plurality of embodiments will be described below, combination of features described in the embodiments as appropriate is originally intended.

### First Embodiment

### Configuration of Photoelectric Conversion Device 100

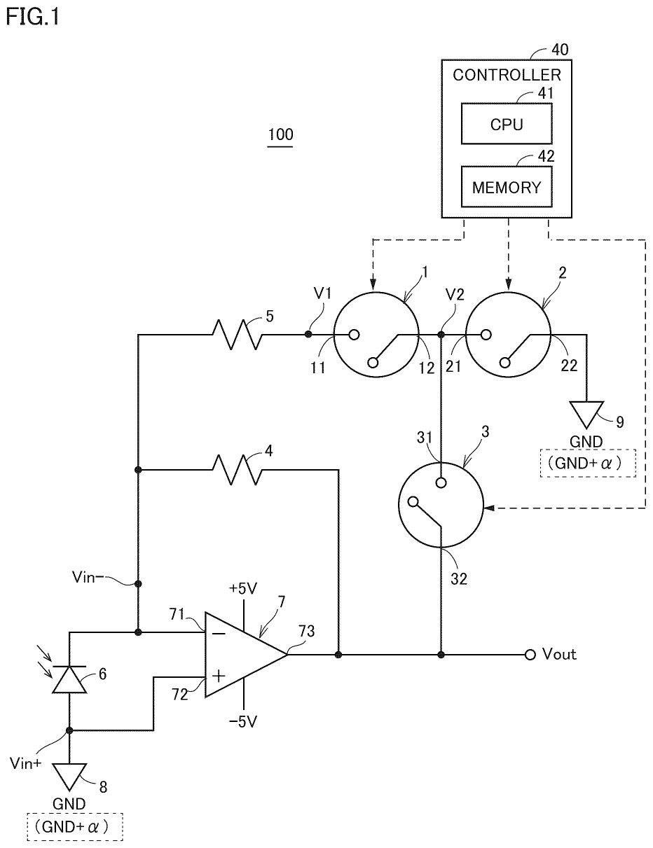

FIG. 1 is a circuit diagram showing a configuration of a photoelectric conversion device 100 in a first embodiment. Photoelectric conversion device 100 includes a first switch 1, a second switch 2, a third switch 3, a first resistor 4, a second resistor 5, a photodetector 6, an amplifier 7, a first terminal 8, and a second terminal 9. Photoelectric conversion device 100 is applicable to various devices including a light receiver, such as a liquid chromatography device and a photometric device.

Photodetector 6 is implemented by a photodiode that outputs a detection signal in accordance with received light. Amplifier 7 is implemented by an operational amplifier including an inverting input terminal 71, a non-inverting input terminal 72, and an output terminal 73. Amplifier 7 is supplied, for example, with +5 V as a positive power supply and supplied, for example, with −5 V as a negative power supply.

First terminal 8 receives a ground potential GND as a reference potential. Photodetector 6 is connected between first terminal 8 and inverting input terminal 71 of amplifier 7. Amplifier 7 has non-inverting input terminal 72 connected to first terminal 8.

First resistor 4 is connected between output terminal 73 and inverting input terminal 71 of amplifier 7. Third switch 3, first switch 1, and second resistor 5 are further connected in series between output terminal 73 and inverting input terminal 71 of amplifier 7. Third switch 3, first switch 1, and second resistor 5 are connected in parallel to first resistor 4 between output terminal 73 and inverting input terminal 71 of amplifier 7.

Second resistor 5 connects output terminal 73 and inverting input terminal 71 of amplifier 7 to each other when first switch 1 and third switch 3 are both set to a conducting state. As first resistor 4 and second resistor 5 are provided between output terminal 73 and inverting input terminal 71 of amplifier 7, amplifier 7 functions as an inverting amplifier.

First resistor 4 is used for setting of a gain of amplifier 7 to a first gain. Second resistor 5 is used for setting of the gain of amplifier 7 to a second gain. First resistor 4 is larger in resistance value than second resistor 5.

For example, relation between the resistance value of first resistor 4 and the resistance value of second resistor 5 is as below. The resistance value of first resistor 4 is set to be larger than the resistance value of second resistor 5 such that a current that flows through first resistor 4 is ignorable when first resistor 4 and second resistor 5 are connected in parallel between output terminal 73 and inverting input terminal 71 of amplifier 7. Therefore, the first gain set with first resistor 4 is larger in gain value than the second gain set with second resistor 5.

Second terminal 9 receives ground potential GND as the reference potential, similarly to first terminal 8. Second switch 2 is provided between second terminal 9 and first switch 1. Second switch 2 can also be explained as being provided between second terminal 9 and third switch 3.

First switch 1 is implemented, for example, by a semiconductor switch. Second switch 2 is implemented, for example, by an analog switch or a mechanical switch. Third switch 3 is implemented, for example, by an analog switch or a mechanical switch.

Specifically, first switch 1 has one end 11 connected to second resistor 5 and has the other end 12 connected to one end 21 of second switch 2 and one end 31 of third switch 3. Second switch 2 has one end 21 connected to the other end 12 of first switch 1 and one end 31 of third switch 3. Third switch 3 has one end 31 connected to the other end 12 of first switch 1 and one end 21 of second switch 2 and has the other end 32 connected to output terminal 73 of amplifier 7.

First switch 1 and third switch 3 are used to switch a resistor for setting of the gain, between first resistor 4 and second resistor 5. Second switch 2 is used for suppression of production of a leakage current in first switch 1 in a state where second resistor 5 is not used as the resistor for setting of the gain.

For example, in such a semiconductor switch as first switch 1, when a potential difference between a potential at one end and a potential at the other end becomes large due to a structure composed of a semiconductor, a leakage current may be produced. In such a semiconductor switch as first switch 1, by setting of the potential at one end and the potential at the other end to be equal, there is no potential difference between the potential at one end and the potential at the other end, and hence the leakage current due to the structure of the semiconductor switch as described previously can be suppressed. Second switch 2 is used to suppress production of the leakage current by setting of the potential at one end 11 of first switch 1 and the potential at the other end 12 of first switch 1 to be equal in the state where second resistor 5 is not used as the resistor for setting of the gain.

Third switch 3 is used not only for switching of the resistor for setting of the gain between first resistor 4 and second resistor 5 but also for a purpose below. When output terminal 73 of amplifier 7 and second terminal 9 are connected to each other in an example where second switch 2 is set to the conducting state for suppression of the leakage current in first switch 1 as described previously, a current flows from output terminal 73 to second terminal 9, which may lower an output voltage Vout from photoelectric conversion device 100. Third switch 3 is controlled to the non-conducting state when second switch 2 is set to the conducting state in order to prevent such lowering in output voltage Vout from photoelectric conversion device 100.

A controller 40 controls photoelectric conversion device 100. For example, as shown with a dashed line in a figure, controller 40 can individually control first switch 1, second switch 2, and third switch 3 by sending control signals to first switch 1, second switch 2, and third switch 3.

For example, controller 40 controls first switch 1, second switch 2, and third switch 3 to set the gain of amplifier 7 with first resistor 4, in setting the gain of amplifier 7 to the first gain (high gain). On the other hand, controller 40 controls first switch 1, second switch 2, and third switch 3 to set the gain of amplifier 7 with second resistor 5, in setting the gain of amplifier 7 to the second gain (low gain). Controller 40 can thus control the gain of amplifier 7 to be switched between the first gain (high gain) and the second gain (low gain).

Controller 40 determines to which of a state of the first gain (high gain) and a state of the second gain (low gain) it makes switching of the gain of amplifier 7, based on data provided from an input device (not shown) connected to controller 40 or control data stored in controller 40.

Controller 40 is implemented by a computer including a central processing unit (CPU) 41, a memory 42 (various storage devices including a read only memory (ROM), a random access memory (RAM), and a non-volatile memory such as a flash memory), and an input and output buffer (not shown) for input and output of various signals.

Various software programs that indicate processing procedures about control by controller 40 are stored in the ROM. CPU 41 develops a software program stored in the ROM on the RAM or the like and executes the same. As such a software program is executed, various types of control such as control of first switch 1, second switch 2, and third switch 3 in photoelectric conversion device 100 are carried out.

### Specific Example of First Switch 1

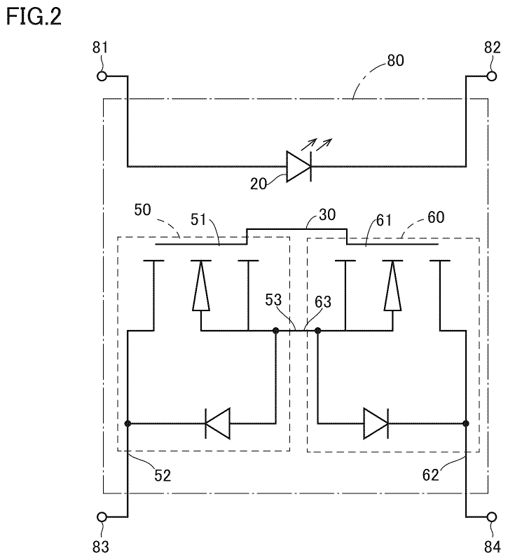

FIG. 2 is a circuit diagram showing an exemplary semiconductor switch to be employed as switch 1. FIG. 2 shows a metal-oxide-semiconductor field-effect transistor (MOSFET) relay 80 by way of example of a semiconductor switch. An example where a semiconductor switch that implements a MOSFET is employed as first switch 1 will be described below.

MOSFET relay 80 includes a first terminal 81, a, second terminal 82, a third terminal 83, a fourth terminal 84, a light emitter 20, a light receiver 30, a first MOSFET 50, and a second MOSFET 60.

First MOSFET 50 is a transistor provided with a gate 51, a drain 52, and a source 53. Second MOSFET 60 is a transistor provided with a gate 61, a drain 62, and a source 63. Source 53 of first MOSFET 50 and source 63 of second MOSFET 60 are connected to each other.

For example, in setting MOSFET relay 80 to a conducting state, for example, controller 40 as shown in FIG. 1 causes a current to flow between first terminal 81 and second terminal 82 so that light emitter 20 emits light. Light emitter 20 is implemented, for example, by a light emitting diode.

Light emitted by light emitter 20 is received by light receiver 30. Light receiver 30 generates a voltage in accordance with reception of light from light emitter 20. A voltage generated by light receiver 30 is applied across gate 51 and source 53 of first MOSFET 50 and across gate 61 and source 63 of second MOSFET 60. First MOSFET 50 and second MOSFET 60 thus operate to allow conduction between third terminal 83 and fourth terminal 84.

When light emitter 20 is not caused to emit light, on the other hand, first MOSFET 50 and second MOSFET 60 do not operate and there is no conduction between third terminal 83 and fourth terminal 84.

Since first terminal 81 and second terminal 82 are on a side where a current for operation of MOSFET relay 80 is inputted, they are called primary-side terminals. Since third terminal 83 and fourth terminal 84 are on a side set to the conducting state in accordance with the current inputted to first terminal 81 and second terminal 82 which are the primary-side terminals, they are called secondary-side terminals.

In an example where such a MOSFET relay 80 is employed as first switch 1 in FIG. 1, for example, third terminal 83 is connected to second resistor 5 in FIG. 1 and fourth terminal 84 is connected to second switch 2 and third switch 3. A control signal from controller 40 in FIG. 1 is then inputted to first terminal 81 or second terminal 82.

In the example where MOSFET relay 80 is employed as first switch 1 in FIG. 1, in the non-conducting state of MOSFET relay 80, second switch 2 functions to set a potential at third terminal 83 at one end and a potential at fourth terminal 84 at the other end to be equal, so that a leakage current can be suppressed in a structure of MOSFET relay 80 as shown in FIG. 2.

In the example where MOSFET relay 80 is employed as first switch 1 in FIG. 1, while MOSFET relay 80 is in the conducting state, the current flows to light emitter 20 and hence a potential difference is produced between first terminal 81 and second terminal 82 on the primary side. In such a conducting state, the potential difference caused by the current that flows to light emitter 20 causes the potential difference between first terminal 81 and second terminal 82 on the primary side and third terminal 83 and fourth terminal 84 on the secondary side, and a leakage current may be produced between the primary side and the secondary side.

When first switch 1 is in the conducting state, however, negative feedback by the current that passes through second resistor 5 functions. In that case, since negative feedback by the current including also the leakage current between the primary side and the secondary side in first switch 1 functions in amplifier 7, the leakage current between the primary side and the secondary side in first switch 1 can be prevented from affecting output voltage Vout from photoelectric conversion device 100.

A semiconductor switch other than MOSFET relay 80 shown in FIG. 2 may be employed as first switch 1 as will be described below.

A semiconductor switch that implements a junction field effect transistor may be employed as first switch 1. The junction field effect transistor is abbreviated as JFET. JFET is a semiconductor switch including a gate terminal, a source terminal, and a drain terminal. In an example where JFET is employed as first switch 1, for example, an n-channel type JFET having an n-type semiconductor embedded in a gate portion has the source terminal connected to second resistor 5 in FIG. 1 and has the drain terminal connected to second switch 2 and third switch 3. A control signal provided from controller 40 in FIG. 1 to JFET controls first switch 1 to one of the conducting state and the non-conducting state.

For example, when the voltage is not applied across the gate terminal and the source terminal of the n-channel JFET in accordance with the control signal from controller 40, first switch 1 is set to the conducting state. When a sufficiently large negative voltage is applied across the gate terminal and the source terminal, on the other hand, first switch 1 is set to the non-conducting state.

Even in an example in which such a semiconductor switch as JFET is employed as first switch 1, potentials at opposing ends of first switch 1 are set to be equal to each other in the non-conducting state of first switch 1, so that the leakage current due to the structure of the semiconductor switch can be suppressed. In such a case, second switch 2 and third switch 3 may each be implemented by the semiconductor switch that implements MOSFET relay 80.

Alternatively, a semiconductor switch that implements a bipolar transistor may be employed as first switch 1. The bipolar transistor is a semiconductor switch including a base terminal, an emitter terminal, and a collector terminal. In an example where the bipolar transistor is employed as first switch 1, for example, an npn transistor containing an n-type semiconductor in an emitter and a collector and containing a p-type semiconductor in a base has the emitter terminal connected to second resistor 5 in FIG. 1 and the collector terminal connected to second switch 2 and third switch 3. First switch 1 is then controlled to one of the conducting state and the non-conducting state in accordance with the control signal provided by controller 40 in FIG. 1 to the bipolar transistor.

For example, when the voltage is applied across the base terminal and the emitter terminal in accordance with the control signal from controller 40, first switch 1 is set to the conducting state. When no voltage is applied across the base terminal and the emitter terminal, on the other hand, first switch 1 is set to the non-conducting state.

Even in an example where a semiconductor switch such as a bipolar transistor is employed as first switch 1, potentials at opposing ends of first switch 1 are set to be equal to each other in the non-conducting state of first switch 1, so that the leakage current due to the structure of the semiconductor switch can be suppressed. In such a case, second switch 2 and third switch 3 may each be implemented by the semiconductor switch that implements MOSFET relay 80.

Alternatively, a semiconductor switch that implements a switching diode may be employed as first switch 1. The diode is a semiconductor switch including a cathode terminal and an anode terminal. In an example where the diode is employed as first switch 1, for example, the cathode terminal is connected to second resistor 5 in FIG. 1 and the anode terminal is connected to second switch 2 and third switch 3. Whether or not a positive voltage is applied across the anode terminal and the cathode terminal sets first switch 1 to one of the conducting state and the non-conducting state.

In an example where such a semiconductor switch as a diode is employed as first switch 1, potentials at opposing ends of first switch 1 are set to be equal to each other in the non-conducting state of first switch 1, so that the current that flows through first switch 1 as a result of application of the positive voltage across the anode terminal and the cathode terminal can be suppressed. In such a case, second switch 2 and third switch 3 may each be implemented by the semiconductor switch that implements MOSFET relay 80.

### Exemplary Control in Photoelectric Conversion Device 100

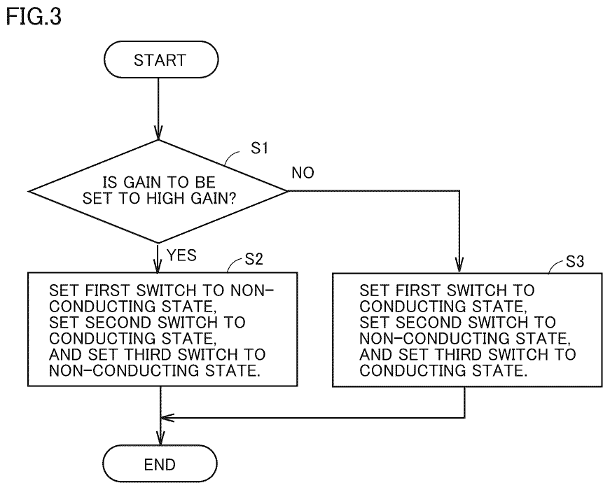

FIG. 3 is a flowchart showing exemplary control of first switch 1, second switch 2, and third switch 3 in photoelectric conversion device 100. Controller 40 carries out control shown in FIG. 3. The flowchart in FIG. 3 will be described below with reference to the configuration in FIG. 1.

In step S1, whether or not a current state is a state in which the gain of amplifier 7 is to be set to the first gain (high gain) is determined. When determination as the state in which the gain of amplifier 7 is to be set to the first gain (high gain) is made in step S1, in step S2, first switch 1 and third switch 3 are controlled to the non-conducting state and second switch 2 is controlled to the conducting state.

In such a state, most of the current in accordance with a quantity of light detected by photodetector 6 flows through first resistor 4 and the current that flows through second resistor 5 is low to an ignorable extent. This is because first switch 1 and third switch 3 are set to the non-conducting state and hence second resistor 5 is not connected between output terminal 73 and inverting input terminal 71 of amplifier 7.

The gain of amplifier 7 is thus set to the first gain (high gain) with first resistor 4. In that case, the current in accordance with the quantity of light detected by photodetector 6 is converted to the voltage by amplifier 7 and first resistor 4 at an amplification factor corresponding to the first gain (high gain), and output voltage Vout amplified as such is outputted from photoelectric conversion device 100.

Thus, in setting of the gain of amplifier 7 to the first gain with first resistor 4, such negative feedback that a most part of the current passes only through first resistor 4 in amplifier 7 is given so that the potential at one end 11 of first switch 1 is set to ground potential GND. This is because, in such negative feedback, owing to a structure of the operational amplifier that implements amplifier 7, a potential Vin− at inverting input terminal 71 of amplifier 7 takes a potential the same as a potential Vin+ at non-inverting input terminal 72 of amplifier 7.

Thus, when first switch 1 is in the non-conducting state, a difference between a potential V1 at one end 11 and a potential V2 at the other end 12 in first switch 1 may cause production of the leakage current as described previously. In photoelectric conversion device 100, however, in setting of the gain of amplifier 7 to the first gain (high gain) with first resistor 4, second switch 2 is set to the conducting state, so that potential V2 at the other end 12 of first switch 1 is set to ground potential GND received by second terminal 9 to which second switch 2 is connected.

Therefore, when first switch 1 is in the non-conducting state, second switch 2 functions to set potential V1 at one end 11 and potential V2 at the other end 12 to be equal (ground potential GND) in first switch 1. Thus, when first switch 1 is in the non-conducting state, second switch 2 can function to suppress production of the leakage current. In that case, third switch 3 is set to the non-conducting state, and hence output voltage Vout is not affected by ground potential GND through second switch 2.

On the other hand, when determination not as the state in which the gain of amplifier 7 is to be set to the first gain (high gain) is made in step S1 described previously, the current state is the state in which the gain of amplifier 7 is to be set to the second gain (low gain). When determination not as the state in which the gain of amplifier 7 is to be set to the first gain (high gain) is made in step S1, in step S3, first switch 1 and third switch 3 are controlled to the conducting state and second switch 2 is controlled to the non-conducting state.

In such a state, most of the current in accordance with the quantity of light detected by photodetector 6 flows through second resistor 5 and the current that flows through first resistor 4 is ignorable. This is because first switch 1 and third switch 3 are set to the conducting state, and hence second resistor 5 is connected between output terminal 73 and inverting input terminal 71 of amplifier 7 and furthermore first resistor 4 is significantly larger in resistance value than second resistor 5. As described previously, in connection with relation between the resistance value of first resistor 4 and the resistance value of second resistor 5, first resistor 4 is set to be larger in resistance value than second resistor 5 such that the current that flows through first resistor 4 is ignorable when first resistor 4 and second resistor 5 are connected in parallel between output terminal 73 and inverting input terminal 71 of amplifier 7.

The gain of amplifier 7 is thus set to the second gain with second resistor 5. In that case, the current in accordance with the quantity of light detected by photodetector 6 is converted to the voltage by amplifier 7 and second resistor 5 and amplified at the amplification factor corresponding to the second gain, and amplified output voltage Vout is outputted from photoelectric conversion device 100. In that case, since second switch 2 has been set to the non-conducting state, output voltage Vout is not affected by ground potential GND through second switch 2.

### Effects Obtained in First Embodiment

Effects obtained in the first embodiment will be listed below.

As described with reference to FIGS. 1 and 3, in setting of the gain of amplifier 7 to the first gain, controller 40 controls first switch 1 and third switch 3 to the non-conducting state and controls second switch 2 to the conducting state, so as to set potential V1 at one end 11 and potential V2 at the other end 12 to be equal in first switch 1. Thus, production of the leakage current by first switch 1 which is the semiconductor switch for switching of the gain of amplifier 7 can be suppressed.

As described with reference to FIGS. 1 and 3, in setting of the gain of amplifier 7 to the first gain, controller 40 controls potential V1 at one end 11 and potential V2 at the other end 12 to the same potential corresponding to ground potential GND in first switch 1. Production of the leakage current by first switch 1 can thus be suppressed.

As described with reference to FIGS. 1 and 3, second resistor 5 is smaller in resistance value than first resistor 4. Therefore, the current that flows through first resistor 4 can be low to an ignorable extent and most of the current can flow through second resistor 5 when first switch 1 and third switch 3 are set to the conducting state. Thus, when first switch 1 and third switch 3 are set to the conducting state, second resistor 5 can be used to set the gain of amplifier 7 to the second gain without particularly providing a switch in first resistor 4.

As described with reference to FIGS. 1 and 3, the first gain is larger in gain value than the second gain. Therefore, the leakage current can be suppressed in amplification at the high gain where influence is greatly exhibited in output voltage Vout from photoelectric conversion device 100 at the time of production of the leakage current.

As described with reference to FIG. 2, the semiconductor switch is implemented by MOSFET relay 80. Therefore, in such a configuration, production of the leakage current in switching of the gain of amplifier 7 can be suppressed.

As described with reference to FIGS. 1 and 3, photodetector 6 is implemented by the photodiode. Therefore, in connection with detection output from photodetector 6, production of the leakage current in switching of the gain of amplifier 7 can be suppressed.

### Second Embodiment

In a second embodiment, an example in which the reference potential in photoelectric conversion device 100 shown in FIG. 1 is set to a potential other than ground potential GND will be described.

In the second embodiment, the potential at first terminal 8 shown in FIG. 1 and the potential at second terminal 9 are set to a potential GND+α as surrounded by a dashed line in FIG. 1. In that case, when first switch 1 and third switch 3 are set to the non-conducting state and second switch 2 is set to the conducting state in step S2 shown in FIG. 3, potential V1 at one end 11 and potential V2 at the other end 12 are set to the same potential GND+α in first switch 1.

According to such a configuration, the second embodiment can obtain an effect similar to the effect obtained in the first embodiment in connection with the configuration as in the first embodiment, and a configuration as below can further be obtained in connection with a configuration different from that in the first embodiment.

As described with reference to FIGS. 1 and 3, in setting the gain of amplifier 7 to the first gain, controller 40 controls potential V1 at one end 11 and potential V2 at the other end 12 to the same potential corresponding to a predetermined potential GND+α different from ground potential GND in first switch 1 so that production of the leakage current by first switch 1 can be suppressed.

### Modification of Embodiments

(1) In the embodiments described previously, an example in which two resistors of first resistor 4 and second resistor 5 are employed as the resistors for setting of the gain of amplifier 7 and these resistors are selectively used by switching to thereby switch magnitude of the gain of amplifier 7 is described. Without being limited as such, at least three resistors may be employed as the resistors for setting of the gain of amplifier 7. In that case, a switch configured similarly to first switch 1 shown in FIG. 1 and a switch configured similarly to second switch 2 are desirably provided for each additional resistor among the at least three resistors.

(2) In the second embodiment described previously, an example in which the potential GND+α is adopted as the reference potential different from ground potential GND is described. Without being limited thereto, a potential GND−α may be adopted as the reference potential different from ground potential GND.

(3) In the embodiments described previously, an example in which the photodiode is employed as photodetector 6 is shown. Without being limited as such, an element that outputs a detection signal in accordance with detected light should only be provided as photodetector 6, and other photodetectors such as a photoelectric cell and a phototransistor may be employed without being limited to the photodiode.

### Aspects

Illustrative embodiments described above are understood by a person skilled in the art as specific examples of aspects below.

(Clause 1) A photoelectric conversion device according to one aspect includes an amplifier including an inverting input terminal, a non-inverting input terminal, and an output terminal, a photodetector connected between the non-inverting input terminal and the inverting input terminal of the amplifier, a first resistor provided between the inverting input terminal and the output terminal of the amplifier to set a gain of the amplifier to a first gain, a second resistor provided between the inverting input terminal and the output terminal of the amplifier to set the gain of the amplifier to a second gain, a first switch implemented by a semiconductor switch having one end connected to the second resistor and the other end connectable to the output terminal of the amplifier, a first terminal connected to the non-inverting input terminal of the amplifier to receive a reference potential, a second terminal that receives the reference potential, a second switch that allows connection between the other end of the first switch and the second terminal, a third switch that allows connection between the other end of the first switch and the output terminal of the amplifier, and a controller that controls the first switch, the second switch, and the third switch. The controller may be configured to control the first switch and the third switch to a conducting state and control the second switch to a non-conducting state in setting the gain of the amplifier to the second gain, and the controller may be configured to control the first switch and the third switch to the non-conducting state and control the second switch to the conducting state to set a potential at the one end and a potential at the other end to be equal in the first switch, in setting the gain of the amplifier to the first gain.

According to the photoelectric conversion device described in Clause 1, in setting of the gain of the amplifier to the first gain, the controller controls the first switch and the third switch to the non-conducting state and controls the second switch to the conducting state so as to set the potential at one end and the potential at the other end to be equal in the first switch. Thus, production of a leakage current by the first switch which is the semiconductor switch for switching of the gain of the amplifier can be suppressed.

(Clause 2) In the photoelectric conversion device described in Clause 1, the reference potential may be a ground potential.

According to the photoelectric conversion device described in Clause 2, in setting of the gain of the amplifier to the first gain, the controller controls the potential at one end and the potential at the other end to the same potential corresponding to the ground potential in the first switch. Production of the leakage current by the first switch can thus be suppressed.

(Clause 3) In the photoelectric conversion device described in Clause 1, the reference potential may be a predetermined potential different from a ground potential.

According to the photoelectric conversion device described in Clause 3, in setting the gain of the amplifier to the first gain, the controller controls the potential at one end and the potential at the other end to the same potential corresponding to the predetermined potential different from the ground potential in the first switch. Production of the leakage current by the first switch can thus be suppressed.

(Clause 4) In the photoelectric conversion device described in any one of Clauses 1 to 3, the second resistor may be smaller in resistance value than the first resistor.

According to the photoelectric conversion device described in Clause 4, the second resistor is smaller in resistance value than the first resistor. Therefore, the current that flows through the first resistor can be low to an ignorable extent and most of the current can flow through the second resistor when the first switch and the third switch are set to the conducting state. Thus, when the first switch and the third switch are set to the conducting state, the second resistor can be used to set the gain of the amplifier to the second gain without particularly providing a switch in the first resistor. (Clause 5) In the photoelectric conversion device described in any one of Clauses 1 to 4, the first gain may be larger in gain value than the second gain.

According to the photoelectric conversion device described in Clause 5, the first gain is larger in gain value than the second gain. Therefore, the leakage current can be suppressed in amplification at the high gain where influence is greatly exhibited in output from the photoelectric conversion device at the time of production of the leakage current.

(Clause 6) In the photoelectric conversion device described in any one of Clauses 1 to 5, the first switch may be implemented by the semiconductor switch that implements a MOSFET relay.

According to the photoelectric conversion device described in Clause 6, in an example where the first switch is the semiconductor switch that implements the MOSFET relay, production of the leakage current in switching of the gain of the amplifier can be suppressed.

(Clause 7) In the photoelectric conversion device described in any one of Clauses 1 to 5, the first switch may be implemented by the semiconductor switch that implements a junction field effect transistor.

According to the photoelectric conversion device described in Clause 7, in an example where the first switch is implemented by the semiconductor switch that implements the junction field effect transistor, production of the leakage current in switching of the gain of the amplifier can be suppressed.

(Clause 8) In the photoelectric conversion device described in any one of Clauses 1 to 5, the first switch may be implemented by the semiconductor switch that implements a bipolar transistor.

According to the photoelectric conversion device described in Clause 8, in an example where the first switch is implemented by the semiconductor switch that implements the bipolar transistor, production of the leakage current in switching of the gain of the amplifier can be suppressed.

(Clause 9) In the photoelectric conversion device described in any one of Clauses 1 to 5, the first switch may be implemented by the semiconductor switch that implements a diode.

According to the photoelectric conversion device described in Clause 9, in an example where the first switch is implemented by the semiconductor switch that implements the diode, production of the leakage current in switching of the gain of the amplifier can be suppressed.

(Clause 10) In the photoelectric conversion device described in any one of Clauses 1 to 9, the photodetector may be implemented by a photodiode.

According to the photoelectric conversion device described in Clause 10, in connection with detection output from the photodetector implemented by the photodiode, production of the leakage current in switching of the gain of the amplifier can be suppressed.

Though embodiments of the present invention have been described, it should be understood that the embodiments disclosed herein are illustrative and non-restrictive in every respect. The scope of the present invention is defined by the terms of the claims and is intended to include any modifications within the scope and meaning equivalent to the terms of the claims.

What is claimed is:

1. A photoelectric conversion device comprising:
an amplifier including an inverting input terminal, a non-inverting input terminal, and an output terminal;
a photodetector connected between the non-inverting input terminal and the inverting input terminal of the amplifier;
a first resistor provided between the inverting input terminal and the output terminal of the amplifier to set a gain of the amplifier to a first gain;
a second resistor provided between the inverting input terminal and the output terminal of the amplifier to set the gain of the amplifier to a second gain;
a first switch comprising a semiconductor switch having one end connected to the second resistor and the other end connectable to the output terminal of the amplifier;
a first terminal connected to the non-inverting input terminal of the amplifier to receive a reference potential;
a second terminal that receives the reference potential;
a second switch that allows connection between the other end of the first switch and the second terminal;
a third switch that allows connection between the other end of the first switch and the output terminal of the amplifier; and
a controller that controls the first switch, the second switch, and the third switch, wherein
the controller is configured to control the first switch and the third switch to a conducting state and control the second switch to a non-conducting state in setting the gain of the amplifier to the second gain, and
the controller is configured to control the first switch and the third switch to the non-conducting state and control the second switch to the conducting state to set a potential at the one end and a potential at the other end to be equal in the first switch, in setting the gain of the amplifier to the first gain.

2. The photoelectric conversion device according to claim 1, wherein
the reference potential is a ground potential.

3. The photoelectric conversion device according to claim 1, wherein
the reference potential is a predetermined potential different from a ground potential.

4. The photoelectric conversion device according to claim 1, wherein
the second resistor is smaller in resistance value than the first resistor.

5. The photoelectric conversion device according to claim 1, wherein
the first gain is larger in gain value than the second gain.

6. The photoelectric conversion device according to claim 1, wherein
the first switch comprises the semiconductor switch that implements a MOSFET relay.

7. The photoelectric conversion device according to claim 1, wherein
the first switch comprises the semiconductor switch that implements a junction field effect transistor.

8. The photoelectric conversion device according to claim 1, wherein
the first switch comprises the semiconductor switch that implements a bipolar transistor.

9. The photoelectric conversion device according to claim 1, wherein
the first switch comprises the semiconductor switch that implements a diode.

10. The photoelectric conversion device according to claim 1, wherein
the photodetector comprises a photodiode.
